(19) United States
(12) Patent Application Publication
(10) Pub. No.: US 2001/0036597 A1
(43) Pub. Date: Nov. 1, 2001

(54) Protective interleaf sheet for planographic printing plates, and packaging method of planographic printing plates

(76) Inventor: Takayuki Usui, Shizuoka-ken (JP)

Correspondence Address: SUGHRUE, MION, ZINN, MACPEAK & SEAS, PLLC, Suite 800, 2100 Pennsylvania Avenue, N.W., Washington, DC, 20037-3213, US

(21) Appl. No.: 09/822,328

(22) Filed: Apr. 2, 2001

(30) Foreign Application Priority Data
Mar. 31, 2000 (JP) 2000-96745

(51) Int. Cl. G03F 7/11

(52) U.S. Cl. 430/273.1; 430/302; 428/537.5; 428/498; 162/168.1; 162/180

(57) ABSTRACT

An interleaf sheet is formed by adding a sizing agent into a slurry of bleached kraft pulp or by applying a sizing agent onto a surface of the interleaf sheet which surface contacts a planographic printing plate. The sizing agent is used for the interleaf sheet so as to easily adjust the release properties of the interleaf sheet with respect to the surface (i.e., a water-soluble polymer layer) of the planographic printing plate and to suppress changes in the release properties with the passage of time.

### BACKGROUND OF THE INVENTION

1. Field of the Invention

The present invention relates to a protective interleaf sheet for protecting an image forming surface of a planographic printing plate which is formed by applying a photosensitive layer or a thermosensitive layer on a support such as an aluminum plate or the like, or an image forming surface of a planographic printing plate which has a water-soluble oxygen cutoff layer as a surface layer on the image forming surface. The present invention also relates to a method of packaging planographic printing plates together with the protective interleaf sheet.

2. Description of the Related Art

As photosensitive planographic printing plates which are highly sensitive to light, those manufactured in the following manner have been known. On a support made of aluminum, an aluminum alloy, or the like, a photosensitive layer is formed which is comprised of a photopolymerizable composition including a compound which contains addition polymerizable ethylenic double bonds, a photopolymerization initiator, an organic polymer compound, and a thermal polymerization inhibitor. Subsequently, as a water-soluble oxygen cutoff layer, a water-soluble polymer layer is laminated onto the photosensitive layer. A desired image is formed on this planographic printing plate by laser exposure. Exposed portions are cured by polymerization, while unexposed portions are removed by dissolution. As a result, a cured relief image is formed on the planographic printing plate.

In order to protect an image forming surface (i.e., the surface of the water-soluble polymer layer) of the above-described planographic printing plate from damage caused by friction between the planographic printing plate and other planographic printing plates, or to carry out satisfactory cutting at the time of processing the planographic printing plate into a product size, an interleaf sheet is adhered to the image forming surface by electrostatic adhesion. A predetermined number of the planographic printing plates, each having the interleaf sheet adhered thereon, are stacked so as to form a stacked sheaf. This stacked sheaf is packaged in a light-shielding internally packaging paper or the like and is then handled.

In recent years, for planographic printing plates which are highly sensitive (i.e., highly sensitive to light), systems for directly making plates by a laser have entered upon the phase of practical use. In many cases, an automatic plate supplying mechanism is provided at automatic plate-making machines, plate setters, or the like which are applied to the systems for directly making plates by a laser. The automatic plate supplying mechanism separates only a single sheet of planographic printing plate from the stacked sheaf of the planographic printing plates, releases the interleaf sheet from the single sheet of planographic printing plate, and automatically supplies the planographic printing plate to the plate-making process. An example of such automatic plate supplying mechanisms is one in which the interleaf sheet is released by being sucked or sucking the planographic printing plate with sucking members such as suckers which are connected to a negative pressure source such as a suction pump.

In general, in order to suck an interleaf sheet in a stable manner by sucking members of the automatic plate supplying mechanism, an interleaf sheet having plastic coated thereon (Japanese Patent Application Publication (JP-B) No. 57-23259), an interleaf sheet whose air permeability is adjusted to 15 to 300 seconds (Japanese Patent Application Laid-Open (JP-A) No. 10-282681), or the like are used as the interleaf sheet which protects the planographic printing plate having the water-soluble oxygen cutoff layer formed thereon. However, a drawback arises in that, although the aforementioned interleaf sheets are satisfactory in being sucked by the sucking members of the automatic plate supplying mechanism, release properties of the interleaf sheets with respect to the planographic printing plate having the water-soluble oxygen cutoff layer formed thereon are not stable. In other words, when the interleaf sheets described above are used, the release properties thereof with respect to the water-soluble oxygen cutoff layer of the planographic printing plate are influenced by various factors and thus becomes unstable. At this time, when the release properties of the interleaf sheet with respect to the planographic printing plate deteriorate, drawbacks such as the following 1 to 3 take place.

1. When the image forming surface or non-image forming surface of the planographic printing plate is sucked and lifted by the sucking members of the automatic plate supplying mechanism, the planographic printing plate is lifted with one or more planographic printing plates adhered thereto via the interleaf sheet adhered to the surface of the planographic printing plate which is opposite to the surface sucked by the sucking members.

2. When the non-image forming surface of the planographic printing plate is sucked and lifted by the sucking members of the automatic plate supplying mechanism, the interleaf sheet is not released from the image forming surface of the planographic printing plate regardless of its frictional contact with a rubber roller for releasing interleaf sheets or air blow, and as a result, the planographic printing plate with the interleaf sheet adhered thereon is supplied to the plate-making process.

3. Also when an attempt is made to release the interleaf sheet from the planographic printing plate by sucking the interleaf sheet by the sucking members of the automatic plate supplying mechanism, since the planographic printing plate is adhered to the interleaf sheet, the interleaf sheet is lifted together with the planographic printing plate.

Further, the above drawbacks 1 to 3 also take place in thermosensitive planographic printing plates.

### SUMMARY OF THE INVENTION

In view of the above-described facts, an object of the present invention is to provide a protective interleaf for planographic printing plates which has satisfactory release properties with respect to photosensitive or thermosensitive planographic printing plates on which an image is formed by laser exposure. It is another object of the present invention to provide a protective interleaf sheet for planographic printing plates which has satisfactory release properties with respect to planographic printing plates having a water-soluble oxygen cutoff layer formed thereon. Yet another object of the present invention is to provide a method of packaging planographic printing plates which enables packaging of planographic printing plates together with the interleaf sheets in a manner suited for the automatic plate supply.

In order to achieve the aforementioned objects, the present inventor achieved the present invention after studying diligently and finding that, by adding to a protective interleaf sheet for planographic printing plates or applying onto the surface of the protective interleaf sheet which contacts a planographic printing plate, various sizing agents which are used for sizing (i.e., preventing blurring) on paper, the release properties of the protective interleaf sheet with respect to the planographic printing plates become stable and appropriate.

That is, the protective interleaf sheet for planographic printing plates according to the present invention covers and thereby protects an image forming surface of a photosensitive or thermosensitive planographic printing plate. Release properties of the protective interleaf sheet with respect to the planographic printing plate are adjusted by adding a sizing agent into or applying it onto the protective interleaf sheet. Alternatively, the interleaf sheet covers and thereby protects the image forming surface of a planographic printing plate having a water-soluble oxygen cutoff layer formed thereon as a surface layer of the image forming surface of the planographic printing plate. Release properties of the protective interleaf sheet with respect to the planographic printing plate are adjusted by adding a sizing agent to or applying it onto the protective interleaf sheet.

The protective interleaf sheet having the above-described structure is manufactured by adding a sizing agent into a slurry of pulp and drying the resulting mixture in a shape of paper, or by applying a sizing agent onto paper which is to be used as a protective interleaf sheet. With either structure, the release properties of the protective interleaf sheet with respect to the planographic printing plate can be adjusted so as to be appropriate. In other words, for example, the protective interleaf sheet adhered onto a planographic printing plate in the manufacturing process can be prevented from being released from the planographic printing plate during storage or transportation. Further, the protective interleaf sheet can be smoothly released from a photosensitive or thermosensitive planographic printing plate by an automatic plate supplying mechanism at the beginning of plate making.

As a sizing agent to be added into the protective interleaf sheet, rosin-based sizing agents and synthetic sizing agents can be used. By adding, in particular, a rosin-based sizing agent such as that in a form of a solution (reinforced rosin), an emulsion, or the like, the release properties of the protective interleaf sheet with respect to the planographic printing plate become satisfactory. Further, as a sizing agent to be applied onto the surface of paper, for example, well known surface sizing agents such as acrylic surface sizing agents, styrene-acrylic copolymer based surface sizing agents, styrene-maleic anhydride copolymer based surface sizing agents, or the like can be used.

Moreover, when a protective interleaf sheet having no sizing agent added thereto is adhered onto a planographic printing plate by electrostatic adhesion or the like, adhesion between the protective interleaf sheet and the planographic printing plate may be unstable. However, if a sizing agent is added into or applied onto the protective interleaf sheet, the release properties of the protective interleaf sheet with respect to the planographic printing plate can be easily adjusted, and can be stabilized. When the protective interleaf sheet having no sizing agent added thereto is adhered, by electrostatic adhesion or the like, to a planographic printing plate having a water-soluble oxygen cutoff layer formed thereon, in particular, adhesion between the protective interleaf sheet and the water-soluble oxygen cutoff layer may be significantly increased, or the release properties of the protective interleaf sheet with respect to the planographic printing plate may change with the passage of time. However, if a sizing agent is added into or applied onto the protective interleaf sheet, the release properties of the protective interleaf sheet with respect to the planographic printing plate can be easily adjusted, and changes in the release properties with the passage of time can also be suppressed.

### BRIEF DESCRIPTION OF THE DRAWINGS

FIG. 1 is a perspective view for explaining a method of packaging planographic printing plates in an internal packaging paper according to an embodiment of the present invention, showing the states of a sheaf of planographic printing plates and the internal packaging paper before packaging is started.

FIG. 2 is a perspective view for explaining the method of packaging planographic printing plates in an internal packaging paper according to the embodiment of the present invention, showing the states of the sheaf of the planographic printing plates and the internal packaging paper while the packaging is carried out.

FIG. 3 is a perspective view for explaining the method of packaging planographic printing plates in an internal packaging paper according to the embodiment of the present invention, showing the states of the sheaf of the planographic printing plates and the internal packaging paper while the packaging is carried out.

FIG. 4 is a perspective view for explaining the method of packaging planographic printing plates in an internal packaging paper according to the embodiment of the present invention, showing the states of the sheaf of the planographic printing plates and the internal packaging paper when the packaging is finished.

### DESCRIPTION OF THE PREFERRED EMBODIMENTS

Hereinafter, a protective interleaf sheet for planographic printing plates and a method of packaging planographic printing plates together with the protective interleaf sheets according to an embodiment of the present invention will be described.

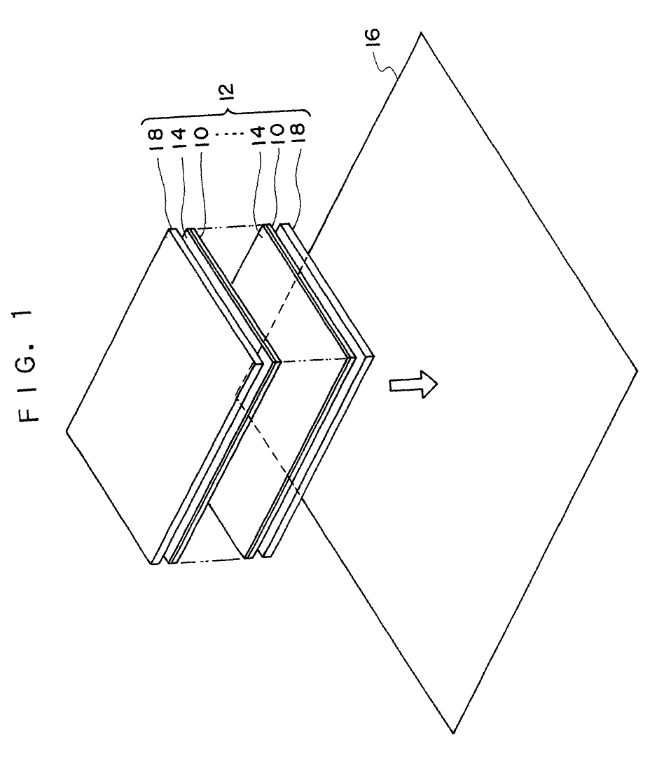

FIGS. 1 through 4 show a process of packaging a sheaf 12 of planographic printing plates 10 in an internal packaging paper 16 according to the embodiment of the present invention. The planographic printing plate 10 is of a so-called highly sensitive type and can be applied to a system for directly making plates by a laser. The planographic printing plate 10 is structured such that a photosensitive layer is disposed on a thin aluminum support formed in a rectangular plate, and further, a water-soluble polymer layer serving as an oxygen cutoff layer is disposed on the photosensitive layer.

As shown in FIG. 1, an interleaf sheet 14 whose main raw material is bleached kraft pulp (wood pulp) is adhered on the surface of the planographic printing plate 10, i.e., the water-soluble polymer layer, by charged adhesion using corona discharge or the like. The interleaf sheet 14 having the above-described structure is adhered before a belt-shaped web, which is a material for the planographic printing plate 10, is cut in the manufacturing process of the planographic printing plate 10. As a result, cutting performance at the time of cutting a belt-shaped web to manufacture planographic printing plates 10 of a product size becomes satisfactory, and damage otherwise caused to an image forming surface of the planographic printing plate 10 due to contact with other planographic printing plates 10 is prevented.

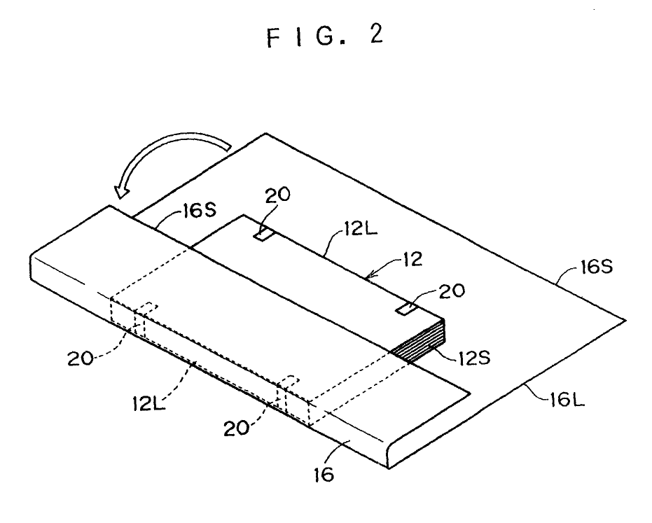

As shown in FIG. 1, when the planographic printing plates 10 each having the interleaf sheet 14 adhered thereon are packaged, the sheaf 12 of the planographic printing plates 10 is formed by stacking a predetermined number of the planographic printing plates 10 in the thickness direction and disposing a protective cardboard 18 so as to cover the uppermost surface and the lowermost surface of the stack of the planographic printing plates 10. As shown in FIG. 2, adhesive tapes 20 are adhered onto the sheaf 12 so that the planographic printing plates 10 and the protective cardboards 18 are not displaced relative to each other. However, the protective cardboard 18 or the tapes 20 may be omitted depending on the type, specification, or the like of the planographic printing plate 10.

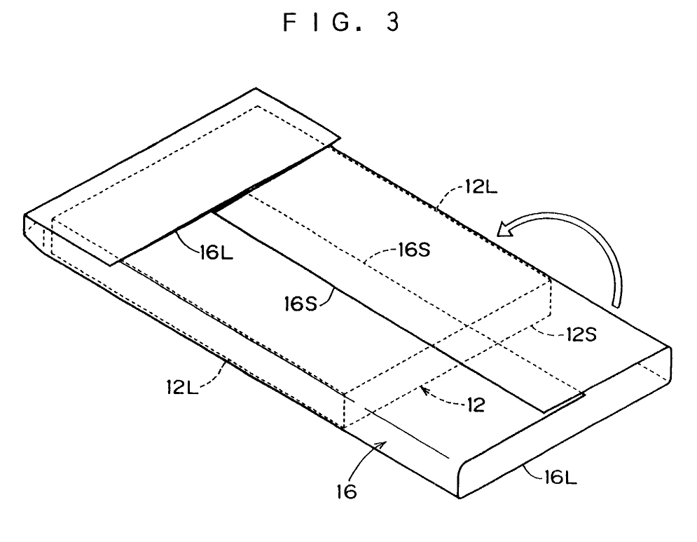

The sheaf 12 of the planographic printing plates 10 structured as described above is packaged in the internal packaging paper 16. The internal packaging paper 16 is formed by a sheet of rectangular aluminum kraft paper having a predetermined size (for example, aluminum kraft paper formed by laminating an aluminum foil having a thickness of 6 μm onto a kraft paper having a basis weight of 83 g/m² using low density polyethylene having a thickness of 13 μm). Long edges 16L of the internal packaging paper 16 have a predetermined length which enables the following process. As shown in FIG. 2, the sheaf 12 is placed onto the substantial center of the internal packaging paper 16 so that long edges 12L of the sheaf 12 are parallel to short edges 16S of the internal packaging paper 16. Then, both short edges 16S of the internal packaging paper 16 are folded along the long edges 12L of the sheaf 12 so that the vicinities of the short edges 16S of the internal packaging paper 16 partially overlap each other (see FIG. 3).

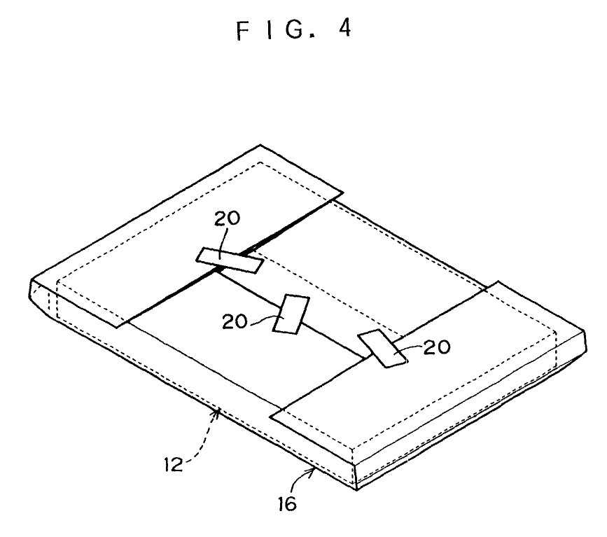

Further, the short edges 16S of the internal packaging paper 16 have a predetermined length which enables the following process. In the state in which the vicinities of the short edges 16S partially overlap each other, the long edge 16L sides of the internal packaging paper 16 are further folded so that the long edges 16L partially overlap a top surface of the sheaf 12 when seen in a plan view (see FIG. 3). In this way, the sheaf 12 is internally packaged in the internal packaging paper 16. As a result, the sheaf 12 is entirely enveloped in the internal packaging paper 16 as shown in FIG. 4. Finally, the internally packaging paper 16 is taped at predetermined positions by the adhesive tapes 20, and thereby fastened so as not to spread or slip off inadvertently. As described above, by packaging the sheaf 12 of the planographic printing plates 10 in the internal packaging paper 16, the planographic printing plates 10 are shielded from light and kept free from moisture, and thus, deterioration in the quality of the planographic printing plates 10 is prevented over a long period of time.

The sheaf 12 of the planographic printing plates 10 which has been packaged in the internal packaging paper 16 in the above-described manner is stored in a corrugated cardboard box (not shown) formed of corrugated cardboard and is handled. The corrugated cardboard box absorbs impact from the exterior or the like and thereby protects the sheaf 12. Further, the corrugated cardboard box acts as a buffer against changes in humidity and temperature, and thus, changes in humidity and temperature in the interior of the corrugated cardboard box are smaller than those outside. Therefore, deterioration in the quality of the planographic printing plate 10 is effectively prevented, and the planographic printing plate 10 can be effectively protected so as not to be damaged by impact from the exterior or the like.

Next, the structure of the interleaf sheet 14 according to the present embodiment will be described. The interleaf sheet 14 is made by adding a sizing agent into a slurry of bleached kraft pulp and drying the resulting mixture in a shape of paper. By using this interleaf sheet 14, release properties of the interleaf sheet 14 with respect to the water-soluble polymer layer which covers the image forming surface of the planographic printing plate 10 can be easily adjusted, and changes in the release properties with the passage of time can be suppressed. Therefore, appropriate adjustment of the release properties of the interleaf sheet 14 with respect to the water-soluble polymer layer of the planographic printing plate 10 can be easily carried out. For example, the interleaf sheet 14 which has been adhered onto the planographic printing plate 10 by electrostatic adhesion in the manufacturing process can be prevented from being released from the planographic printing plate 10 during storage or transportation. Further, when plate making is started, the interleaf sheet 14 can be smoothly released from the planographic printing plate 10 by an automatic plate supplying mechanism.

As the sizing agent to be added into the slurry of bleached kraft pulp, rosin-based sizing agents and synthetic sizing agents may be used. By adding, in particular, rosin-based sizing agents such as those in a form of a solution (reinforced rosin), an emulsion, or the like, the release properties of the interleaf sheet 14 with respect to the water-soluble polymer layer of the planographic printing plate 10 become satisfactory.

The release properties of the interleaf sheet 14 with respect to the image forming surface (i.e., the water-soluble polymer layer) of the planographic printing plate 10 can also be adjusted by applying a surface sizing agent onto the surface of kraft paper which has been made by drying a slurry of bleached kraft pulp. In this way, the release properties of the interleaf sheet 14 with respect to the planographic printing plate 10 become satisfactory. Examples of the surface sizing agent which can be used are well known surface sizing agents such as acrylic sizing agents, styrene-acrylic copolymer based sizing agents, styrene-maleic anhydride copolymer based sizing agents, and the like.

Further, the interleaf sheet 14 of the present embodiment can also be used as the interleaf sheet for protecting the image forming surface of a planographic printing plate having no water-soluble oxygen cutoff layer formed thereon. In this case, because of the nature of the planographic printing plate having no water-soluble oxygen cutoff layer formed thereon, significantly strong adhesion of the plate to the protective interleaf sheet hardly takes place. Accordingly, the release properties of the protective interleaf sheet 14 with respect to the planographic printing plate may be satisfactory although its effect is small comparing with the case in which the planographic printing plate 10 having a water-soluble oxygen cutoff layer formed thereon is used.

Moreover, as for the protective interleaf sheet 14 of the present embodiment, wood pulp is used as the main raw material. However, even if the main raw material is synthetic pulp or a mixture of wood pulp and synthetic pulp, the release properties of the protective interleaf sheet 14 with respect to the planographic printing plate 10 can be adjusted by a sizing agent.

Plate-making processings such as exposure, development, gum coating, and the like are carried out on the photosensitive layer of the planographic printing plate 10. The processed planographic printing plate 10 is set in a printing machine, and ink is applied to the plate, thereby printing characters, images, or the like on paper. Note that the planographic printing plate 10 of the present embodiment is one before processings (such as exposure, development, and the like) necessary for printing are carried out. The planographic printing plate 10 may be occasionally referred to as a planographic printing original plate or a planographic printing plate material.

A specific structure of the planographic printing plate 10 is not limited as long as it has the above-mentioned structure. For example, by manufacturing planographic printing plates for plate printing with a laser in a heat mode system or a photon system, it is possible to provide planographic printing plates which can be made directly from digital data.

Further, the planographic printing plate 10 which can be applied for various plate-making methods can be provided by selecting various components in the photosensitive layer or the thermosensitive layer. Specific examples of the planographic printing plate 10 according to the present invention may include the following (1) to (11)

(1) A planographic printing plate whose photosensitive layer contains a compound which generates acid in the presence of an infrared absorption agent and heat and a compound in which crosslinking is formed by an acid.

(2) A planographic printing plate whose photosensitive layer contains a compound which becomes soluble in alkali in the presence of an infrared absorption agent and heat.

(3) A planographic printing plate whose photosensitive layer is comprised of two layers, i.e., an oxygen cutoff layer and a layer which contains a compound generating a radical by irradiation of a laser beam, a binder which is soluble in alkali, and a multifunctional monomer or prepolymer.

(4) A planographic printing plate whose photosensitive layer is comprised of two layers, i.e., a physical development core layer and a silver halide emulsion layer.

(5) A planographic printing plate whose photosensitive layer is comprised of three layers, i.e., a polymerization layer containing a multifunctional monomer and a multifunctional binder, a layer containing silver halide and a reducing agent, and an oxygen cutoff layer.

(6) A planographic printing plate whose photosensitive layer is comprised of two layers, i.e., a layer containing novorak resin and naphtoquinonediazide, and a layer containing silver halide.

(7) A planographic printing plate whose photosensitive layer contains an organic photoconductor.

(8) A planographic printing plate whose photosensitive layer is comprised of two to three layers, i.e., a laser beam absorbing layer which is removed by irradiation of a laser beam, a lipophilic layer and/or a hydrophilic layer.

(9) A planographic printing plate whose photosensitive layer contains a compound which absorbs energy to generate acid, a high molecular compound which has, at a side chain thereof, a functional group which generates sulphonic acid or carboxylic acid in the presence of an acid, and a compound which imparts energy to an acid generating agent by absorbing visible light.

(10) A planographic printing plate whose photosensitive layer contains a quinondiazide compound and novorak resin.

(11) A planographic printing plate whose photosensitive layer contains a compound which is decomposed by light or ultraviolet light and forms a crosslinking structure in itself or with other molecules within the layer, and a binder which is soluble in alkali.

Further, the planographic printing plates 10 of the present embodiment (i.e., the planographic printing plates of the above (1) to (11)) may be supplied to the plate-making process by being set in the form of the sheaf 12 in an automatic plate-making machine or a so-called plate setter having an automatic plate supplying function. As will be described later, by using the interleaf sheet 14 with a sizing agent added therein, the planographic printing plate 10 can be prevented from being conveyed together with interleaf sheet 14 to the automatic plate-making machine or the like. However, in actual use, by a user of planographic printing plates using the interleaf sheets according to the present invention regardless of whether the planographic printing plates 10 are supplied by an automatic plate supplying mechanism or supplied by hand (i.e., as a concern preceding how the plates are to be supplied), the release properties of the interleaf sheet with respect to the planographic printing plate become satisfactory, and therefore, working efficiency can be improved.

### EXAMPLES

Next, the protective interleaf sheet for planographic printing plates according to the embodiment of the present invention will be described comparing with a protective interleaf sheet of Comparative Example.

Table 1 shows the structures of interleaf sheets in Examples 1 and 2 according to the present invention and the interleaf sheet in Comparative Example.

TABLE 1

| | | | Comparative |
|---|---|---|---|
| | Example 1 | Example 2 | Example |
| Sizing agent | Rosin-based | Synthetic sizing | Not added |
| | sizing agent | agent | |
| Addition amount of | 0.2 | 0.4 | None |
| sizing agent | | | |
| (% by weight) | | | |
| Basis weight (g/m²) | 45 | 38 | 30 |
| Bekk smoothness of | 265 | 65 | 212 |
| image forming | | | |
| surface (seconds) | | | |
| Bekk smoothness of | 12 | 55 | 15 |
| non-image forming | | | |
| surface (seconds) | | | |
| Air permeability | 15 | 11 | 15 |
| (seconds) | | | |
| Moisture content (%) | 4 to 5 | 5 to 7 | 4 to 5 |

The interleaf sheets in Examples 1 and 2 and Comparative Example shown in above Table 1 were each adhered by electrostatic adhesion onto an image forming surface of a planographic printing plate having a water-soluble polymer layer formed thereon. Sheaves of the planographic printing plates were respectively loaded in an automatic plate supplying mechanism, and three types of evaluation tests A to C regarding the release properties of the interleaf sheets were carried out as follows.

### Evaluation Test A

The image forming surface or the non-image forming surface of each of the planographic printing plates was sucked and lifted by a sucking member of the automatic plate supplying mechanism. In this state, it was evaluated whether or not the interleaf sheet, which was adhered on the surface opposite to the surface of the planographic printing plate sucked by the sucking member, was released from the planographic printing plate.

### Evaluation Test B

The non-image forming surface of each of the planographic printing plates was sucked and lifted by the sucking member of the automatic plate supplying mechanism. In this state, it was evaluated whether or not the interleaf sheet was released from the image forming surface by frictional contact with a rubber roller or by air blow.

### Evaluation Test C

The interleaf sheet adhered on the image forming surface of each of the planographic printing plates was sucked and lifted by the sucking member of the automatic plate supplying mechanism. In this state, it was evaluated whether or not the planographic printing plate was released from the interleaf sheet.

Table 2 shows the results of the evaluation tests A to C for the interleaf sheets in Examples 1 and 2, and Comparative Example.

TABLE 2

| Sizing agent | Added | Added | Not added |
|---|---|---|---|
| Type of sizing agent | Rosin-based | Synthetic sizing | None |
| | sizing agent | agent | |
| Test results | ⊚ | ◯ | X |

As for the evaluation marks in the column of “Test results” in above Table 2, “⊚” means that there is no problem with the release properties of the interleaf sheet with respect to the planographic printing plate, “◯” means that there is no problem in practical use with the release properties of the interleaf sheet with respect to the planographic printing plate although they are somewhat poorer comparing with “⊚”, and “X” means that the interleaf sheet was not released from the planographic printing plate and that the planographic printing plate may be supplied to the plate-making process together with the interleaf sheet or other planographic printing plates.

As can also be clear from Table 2, the release properties of the interleaf sheet having a rosin-based sizing agent added therein with respect to the planographic printing plate are the most satisfactory. As for the release properties of the interleaf sheet having a synthetic sizing agent added therein with respect to the planographic printing plate, there is no problem with them in practical use. However, when the interleaf sheet made having no sizing agent added therein is used, the release properties thereof with respect to the planographic printing plate become unstable. As a result, separation of a single sheet of planographic printing plate by the automatic plate supplying mechanism from the sheaf of the planographic printing plates may not be possible. Further, release and thus removal of the interleaf sheet from the separated planographic printing plate may not be possible.

What is claimed is:

1. A protective interleaf sheet for planographic printing plates which covers and thereby protects an image forming surface of one of a photosensitive planographic printing plate and a thermosensitive planographic printing plate, wherein release properties with respect to the planographic printing plate are adjusted by adding a sizing agent into or applying it onto the protective interleaf sheet.

2. A protective interleaf sheet for planographic printing plates according to claim 1, wherein a rosin-based sizing agent is added as the sizing agent.

3. A protective interleaf sheet for planographic printing plates according to claim 2, wherein the rosin-based sizing agent is in a form of a solution.

4. A protective interleaf sheet for planographic printing plates according to claim 2, wherein the rosin-based sizing agent is in a form of an emulsion.

5. A protective interleaf sheet for planographic printing plates which covers and thereby protects an image forming surface of one of a photosensitive planographic printing plate and a thermosensitive planographic printing plate on which an image is formed by laser exposure, wherein release properties with respect to the planographic printing plate are adjusted by adding a sizing agent into or applying it onto the protective interleaf sheet.

6. A protective interleaf sheet for planographic printing plates according to claim 5, wherein a rosin-based sizing agent is added as the sizing agent.

7. A protective interleaf sheet for planographic printing plates according to claim 6, wherein the rosin-based sizing agent is in a form of a solution.

8. A protective interleaf sheet for planographic printing plates according to claim 6, wherein the rosin-based sizing agent is in a form of an emulsion.

9. A protective interleaf sheet for planographic printing plates which covers and thereby protects an image forming surface of a planographic printing plate having a water-soluble oxygen cutoff layer formed on the image forming surface as a surface layer, wherein release properties with respect to the planographic printing plate are adjusted by adding a sizing agent into or applying it onto the protective interleaf sheet.

10. A protective interleaf sheet for planographic printing plates according to claim 9, wherein a rosin-based sizing agent is added as the sizing agent.

11. A protective interleaf sheet for planographic printing plates according to claim 10, wherein the rosin-based sizing agent is in a form of a solution.

12. A protective interleaf sheet for planographic printing plates according to claim 10, wherein the rosin-based sizing agent is in a form of an emulsion.

13. A method of packaging planographic printing plates comprising the steps of:
covering each image forming surface of a plurality of planographic printing plates with a protective interleaf sheet for planographic printing plates which is adapted to cover and thereby protect an image forming surface of one of a photosensitive planographic printing plate and a thermosensitive planographic printing plate, release properties of said protective interleaf sheet for planographic printing plates with respect to the planographic printing plate being adjusted by adding a sizing agent into or applying it onto the protective interleaf sheet; and
packaging, in a packaging material, a stacked sheaf formed by stacking in a thickness direction the plurality of planographic printing plates each covered with the protective interleaf sheet.

14. A method of packaging planographic printing plates comprising the steps of:
covering each image forming surface of a plurality of planographic printing plates with a protective interleaf sheet for planographic printing plates which is adapted to cover and thereby protect an image forming surface of one of a photosensitive planographic printing plate and a thermosensitive planographic printing plate, release properties of said protective interleaf sheet for planographic printing plates with respect to the planographic printing plate being adjusted by adding a rosin-based sizing agent into or applying it onto the protective interleaf sheet; and
packaging, in a packaging material, a stacked sheaf formed by stacking in a thickness direction the plurality of planographic printing plates each covered with the protective interleaf sheet.

15. A method of packaging planographic printing plates comprising the steps of:
covering each image forming surface of a plurality of planographic printing plates with a protective interleaf sheet for planographic printing plates which is adapted to cover and thereby protect an image forming surface of one of a photosensitive planographic printing plate and a thermosensitive planographic printing plate on which an image is formed by laser exposure, release properties of said protective interleaf sheet being adjusted by adding a sizing agent into or applying it onto the protective interleaf sheet; and
packaging, in a packaging material, a stacked sheaf formed by stacking in a thickness direction the plurality of planographic printing plates each covered with the protective interleaf sheet.

16. A method of packaging planographic printing plates comprising the steps of:
covering each image forming surface of a plurality of planographic printing plates with a protective interleaf sheet for planographic printing plates which is adapted to cover and thereby protect an image forming surface of one of a photosensitive planographic printing plate and a thermosensitive planographic printing plate on which an image is formed by laser exposure, release properties of said protective interleaf sheet being adjusted by adding a rosin-based sizing agent into or applying it onto the protective interleaf sheet; and
packaging, in a packaging material, a stacked sheaf formed by stacking in a thickness direction the plurality of planographic printing plates each covered with the protective interleaf sheet.

17. A method of packaging planographic printing plates comprising the steps of:
covering each image forming surface of a plurality of planographic printing plates with a protective interleaf sheet for planographic printing plates which is adapted to cover and thereby protect an image forming surface of a planographic printing plate having a water-soluble oxygen cutoff layer formed on the image forming surface as a surface layer, release properties of said protective interleaf sheet being adjusted by adding a sizing agent into or applying it onto the protective interleaf sheet; and
packaging, in a packaging material, a stacked sheaf formed by stacking in a thickness direction the plurality of planographic printing plates each covered with the protective interleaf sheet.

18. A method of packaging planographic printing plates comprising the steps of:
covering each image forming surface of a plurality of planographic printing plates with a protective interleaf sheet for planographic printing plates which is adapted to cover and thereby protect an image forming surface of a planographic printing plate having a water-soluble oxygen cutoff layer formed on the image forming surface as a surface layer, release properties of said protective interleaf sheet being adjusted by adding a rosin-based sizing agent into or applying it onto the protective interleaf sheet; and
packaging, in a packaging material, a stacked sheaf formed by stacking in a thickness direction the plurality of planographic printing plates each covered with the protective interleaf sheet.
